(19) United States
(12) Patent Application Publication
(10) Pub. No.: US 2014/0048128 A1
(43) Pub. Date: Feb. 20, 2014

(54) SURFACE MOUNTABLE SOLAR RECEIVER WITH INTEGRATED THROUGH SUBSTRATE INTERCONNECT AND OPTICAL ELEMENT CRADLE

(71) Applicant: SEMPRIUS, INC., Durham, NC (US)

(72) Inventors: Matthew Meitl, Durham, NC (US); Christopher Bower, Raleigh, NC (US)

(73) Assignee: Semprius, Inc., Durham, NC (US)

(21) Appl. No.: 13/827,623

(22) Filed: Mar. 14, 2013

Related U.S. Application Data
(60) Provisional application No. 61/683,958, filed on Aug. 16, 2012.

(51) Int. Cl. H01L 31/052

(52) U.S. Cl. CPC H01L 31/0525
USPC 136/255; 136/259; 438/65; 438/68; 438/98

(57) ABSTRACT

A concentrator-type photovoltaic (CPV) device includes a solar cell comprising a substrate including a light receiving surface and a mounting surface opposite the light receiving surface. A conductive through-substrate interconnect having insulated sidewalls extends through the substrate from the mounting surface to the light receiving surface to provide an electrical connection to a conductive terminal on the light receiving surface. A lens support structure is formed on the light receiving surface, and a lens element is provided on the support structure opposite the light receiving surface. The support structure supports and aligns the lens element with the light receiving surface to concentrate incident light thereon. Related fabrication processes are also discussed.

### RELATED APPLICATIONS

The present application claims priority from U.S. Provisional Patent Application No. 61/683,958 entitled “Surface Mountable Solar Receiver with Integrated Through Substrate Interconnect and Optical Element Cradle” filed on Aug. 16, 2012, the disclosure of which is incorporated by reference herein in its entirety. The present application is also related to U.S. Provisional Patent Application No. 61/677,892 entitled “Surface-Mountable Lens Cradles And Interconnection Structures For Concentrator-Type Photovoltaic Devices” filed on Jul. 31, 2012, the disclosure of which is incorporated by reference herein in its entirety.

### FIELD

The present invention relates to photovoltaic devices and methods of forming same and, more particularly, to concentrator-type photovoltaic devices and methods of forming same.

### BACKGROUND

Concentrator Photovoltaics (CPV) is an increasingly promising technology for renewable electricity generation in sunny environments. CPV uses relatively inexpensive, efficient optics to concentrate sunlight onto solar cells, thereby reducing the cost requirements of the semiconductor material and enabling the economic use of more efficient cells, for example multi junction solar cells. This high efficiency at reduced costs, in combination with other aspects, makes CPV among the most economical renewable solar electricity technology in sunny climates and geographic regions.

CPV module designs that use small solar cells (for example, cells that are smaller than about 4 mm²) may benefit significantly because of the ease of energy extraction from such cells. The superior energy extraction characteristics apply to both usable electrical energy and waste heat, potentially allowing a better performance-to-cost ratio than CPV module designs that use larger cells. However, the production of small solar cell designs may introduce technical challenges, for example, the interconnection of arrays with high part-count and the demanding spatial tolerances between small cells and optical components.

### SUMMARY

According to some embodiments, a concentrator-type photovoltaic device includes a conductive through-substrate interconnect or via that establishes electrical connection between (e.g., electrical contact with) a top conductive terminal of a multi-junction concentrator photovoltaic cell that is on or adjacent a light receiving surface thereof and an electrical node on a back-side or mounting surface of a substrate (such as a growth substrate). A cradle structure is provided on the cell, and includes features for supporting a secondary optical element with good spatial registration between the optical element and the light-receiving active area of the cell. The cradle structure may be optically transparent and the optical element may be a spherical lens in some embodiments. The cell is configured for surface mounting and/or other attachment to a backplane or other support substrate. The cell may be configured to be self-aligned to the backplane or other supporting substrate by solder reflow to provide good spatial registration between features of the cradle, features on the backplane or supporting substrate, and features on the concentrator photovoltaic cell.

According to further embodiments, a photovoltaic device includes a multi-junction solar cell designed for high concentration. The solar cell may be a three junction device (that is, including three sub-cells, each reactive to different wavelengths of light), but can also be a four or five junction device in some embodiments. The different sub-cells or junctions can be grown using MOCVD or MBE. The electrical connection between the conductive terminal or metal grid on the top-side of the device and a mounting pad on the backside of the device is provided using a through substrate interconnect, also referred to herein as a through substrate via (TSV) or through wafer via. The through substrate interconnect is electrically isolated from the growth substrate and from sub-cells other than the top or uppermost cell.

In some embodiments, the photovoltaic device may have relatively small physical dimensions. For example, the lateral dimensions of the CPV device can be about 2 mm or less (e.g., a surface area of <4 mm²) and the device may have a thickness of about 1 mm or less.

In some embodiments, the photovoltaic device can be surface-mountable. Thus, the photovoltaic device can be directly electrically mated to a relatively large backplane or support substrate (for example, as part of an array of CPV receivers) without additional interconnection steps. The photovoltaic device can have two electrical contact pads on the back surface of the wafer or substrate. One pad can be electrically interconnected to the top conductive terminal or metal grid present on the top-side of the concentrator solar cell, while the other pad can be electrically interconnected to the backside of the wafer or substrate on which the concentrator solar cell was grown, thereby connecting with a bottom or lower sub-cell.

In some embodiments, the photovoltaic device includes an anti-reflection coating on the light receiving surface of the solar cell.

In some embodiments, the photovoltaic device may be a CPV device including a mechanical cradle structure configured to support and align a lens element, such as a spherical glass ball lens. The mechanical cradle may be optically transparent in order to reduce and/or prevent obscuring of incident solar radiation.

According to yet other embodiments, a concentrator-type photovoltaic (CPV) device includes a solar cell comprising a substrate including a light receiving surface having a conductive terminal thereon, and a mounting surface opposite the light receiving surface. A conductive through-substrate interconnect having insulated sidewalls extends through the substrate from the mounting surface toward the light receiving surface to electrically contact the conductive terminal. A lens support structure is provided on the light receiving surface, and a lens element is provided on the lens support structure opposite the light receiving surface. The support structure supports and aligns the lens element with the light receiving surface to focus incident light thereon.

In some embodiments, the solar cell may be a multi junction device including a plurality of sub-cells on the light-receiving surface, where at least two of the sub-cells are reactive to a different wavelength of light. The substrate may be a growth substrate for the sub-cells. The through-substrate interconnect may be electrically connected to one of the sub-cells, but may be electrically isolated from other ones of the sub-cells and/or the substrate.

In some embodiments, the lens support structure may be an optically transparent material. The lens support structure may cover a majority of the light receiving surface.

In some embodiments, the lens support structure may be a photo-definable material, a molded material, and/or a plated metal structure.

In some embodiments, the lens element may be a spherical lens element. The lens support structure may include features having widths less than respective heights thereof that are configured to support and self-align the spherical lens element with the light receiving surface.

In some embodiments, the solar cell may be a surface-mountable device, and the mounting surface may be provided on a backplane substrate. A solder connection may be provided between the through-substrate interconnect adjacent the mounting surface and an electrical contact on the substrate. The solar cell and the support structure thereon may be configured to be self-aligned to features of the substrate by reflow of the solder connection.

In some embodiments, the light receiving surface may have an area of about 4 mm² or less.

In some embodiments, an anti-reflection coating may be provided on the light receiving surface of the solar cell, between the light receiving surface and the lens support structure.

According to still further embodiments, a method of fabricating a concentrator-type photovoltaic (CPV) device includes forming one or more light reactive junction layers and a conductive terminal on a light receiving surface of a substrate to define a solar cell. A conductive through-substrate interconnect having insulated sidewalls is formed extending into the substrate from a mounting surface toward the light receiving surface opposite the mounting surface. The through-substrate interconnect is formed to provide an electrical connection between the mounting surface and the conductive terminal on the light receiving surface. A lens support structure is formed on the light receiving surface of the solar cell. The substrate is singulated, and a lens element is provided on the support structure opposite the light receiving surface of the solar cell. The support structure supports and aligns the lens element with the light receiving surface to concentrate incident light thereon,

In some embodiments, forming the at least one light reactive layer may include epitaxially growing a plurality of light reactive layers on the light receiving surface of the substrate, where at least two of the light reactive layers are reactive to a different wavelength of light.

In some embodiments, the through-substrate interconnect may be electrically connected to one of the light reactive layers, but may be electrically isolated from other ones of the light reactive layers and the substrate.

In some embodiments, forming the through-substrate interconnect may include masking and etching the mounting surface to define an opening therein extending toward the light receiving surface, forming an insulating layer on sidewalls of the opening, and forming a conductive layer on the insulating layer in the opening. The conductive layer in the opening may electrically contact the conductive terminal on the light receiving surface.

In some embodiments, forming the through-substrate interconnect may further include selectively etching a portion of the insulating layer between the sidewalls of the opening prior to forming the conductive layer in the opening.

In some embodiments, the opening in the mounting surface may be aligned with the conductive terminal on the light receiving surface, and the selective etching may expose a portion of the conductive terminal.

In some embodiments, the conductive layer may be a first conductive layer, and a second conductive layer may be formed to extend from the first conductive layer in the opening to the conductive terminal on the light receiving surface.

In some embodiments, the light receiving surface may be patterned to expose the opening and to define a mesa structure including the at least one light reactive layer prior to forming the second conductive layer.

In some embodiments, the conductive layer may be a first conductive layer. Forming the through-substrate interconnect may further include selectively etching a portion of the insulating layer between the sidewalls of the opening after forming the conductive layer therein to expose the first conductive layer, and forming a second conductive layer extending from the first conductive layer in the opening to the conductive terminal on the light receiving surface.

In some embodiments, the light receiving surface may be patterned to expose the portion of the insulating layer and to define a mesa structure including the at least one light reactive layer prior to forming the second conductive layer.

In some embodiments, forming the lens support structure may include curing the lens support structure on the light receiving surface. The lens support structure may be an optically transparent material.

In some embodiments, prior to providing the lens element, the solar cell may be surface-mounted on a backplane substrate such that a solder connection is provided between an electrical contact on the backplane substrate and a portion of the through-substrate interconnect adjacent the mounting surface. The solder connection may be reflowed to align the solar cell and the support structure thereon with features of the backplane substrate.

According to yet further embodiments, a method of fabricating a concentrator-type photovoltaic (CPV) device includes forming a lens support structure on a light receiving surface of a solar cell on a substrate using a photolithography process, a molding process, and/or a plating process, and providing a lens element on the lens support structure opposite the light receiving surface.

In some embodiments, the substrate including the lens support structure thereon may be singulated prior to providing the lens element on the lens support structure.

In some embodiments, the lens support structure may be an optically transparent material.

In some embodiments, the lens support structure may be formed to cover a majority of the light receiving surface.

According to yet still further embodiments, a concentrator-type photovoltaic (CPV) device includes a solar cell comprising a substrate including a light receiving surface having a conductive terminal thereon and a mounting surface opposite the light receiving surface. A lens support structure including a photo-definable material, a molded material, and/or a plated metal structure is provided on the light receiving surface, and a lens element is provided on the lens support structure opposite the light receiving surface.

Other methods, systems, and/or devices according to some embodiments will become apparent to one with skill in the art upon review of the following drawings and detailed description. It is intended that all such additional embodiments, in addition to any and all combinations of the above embodiments, be included within this description, be within the scope of the invention, and be protected by the accompanying claims.

### BRIEF DESCRIPTION OF THE DRAWINGS

The above and other features and advantages of the present invention will become evident upon review of the following summarized and detailed descriptions in conjunction with the accompanying drawings:

FIG. 1 is a cross-sectional view illustrating a lens cradle and through-substrate interconnection structure in accordance with embodiments of the present invention.

FIGS. 2A-2I are cross-sectional views illustrating operations for fabricating a lens cradle and through-substrate interconnection structure in accordance with some embodiments of the present invention.

FIGS. 3A-3J are cross-sectional views illustrating operations for fabricating a lens cradle and through-substrate interconnection structure in accordance with further embodiments of the present invention.

FIG. 4 is a flowchart illustrating operations for fabricating a lens cradle and through-substrate interconnection structure in accordance with further embodiments of the present invention.

FIGS. 5A-5K are cross-sectional views illustrating operations for fabricating a lens cradle and through-substrate interconnection structure in accordance with the flowchart of FIG. 4.

FIG. 6 is a plan view illustrating a layout of a solar cell that includes through-substrate vias and a lens support structure in accordance with some embodiments of the present invention.

FIG. 7 is a plan view illustrating an array of vias etched through a germanium growth substrate in accordance with some embodiments of the present invention.

FIG. 8 is a cross-sectional micrograph illustrating lens support structures composed of a photo-definable epoxy in accordance with some embodiments of the present invention.

FIG. 9 is a plan view illustrating a partially formed solar cell that includes a lens spacer made of photo-definable epoxy in accordance with some embodiments of the present invention.

FIG. 10A is a photograph illustrating an array of solar cells including lens support structures in accordance with some embodiments of the present invention.

FIG. 10B illustrates an enlarged view of FIG. 10A,

FIG. 11A is a photograph illustrating an array of solar cells surface-mounted to a ceramic interposer in accordance with some embodiments of the present invention.

FIG. 11B illustrates an enlarged view of FIG. 11A.

### DETAILED DESCRIPTION OF EMBODIMENTS

In order to benefit from advantages provided by smaller solar cells (e.g., cells having a surface area of less than about 4 mm² and a thickness of less than about 1 mm), manufacturing processes and designs may be needed to address the associated technical challenges and costs, namely the interconnection of arrays with high part-count and the demanding spatial tolerances between small cells and optical components in rapid and inexpensive ways.

Accordingly, embodiments of the present invention provide devices and manufacturing processes that allow for rapid and inexpensive electrical interconnection and accurate positioning of small cells onto a relatively larger-area electrical backplane to define a CPV receiver array. Embodiments of the present invention also provide for precise alignment and attachment of secondary optical elements to each of the cells in the array. Some embodiments of the present invention may be used in CPV modules that use spherical ball lenses as secondary optical elements. In particular, some embodiments of the present invention include “cradle” structures that can be fabricated directly on and aligned with the light-receiving active area of a concentrator solar cell. The cradle structures can include a mechanical guide that is configured to allow a spherical (or “ball”) lens and/or other lens types to gravitationally self-align to the solar cell. The mechanical cradle structures may be substantially compact such that they occupy or otherwise obstruct a relatively small portion of the light-receiving surface area of a solar cell wafer. The cradle structures may also be optically transparent with respect to incident light in some embodiments.

FIG. 1 illustrates a CPV device 10 including a lens cradle 8 that may be formed on a backplane or other support substrate 4 by one or more of photolithography, electroplating, and molding. In particular, FIG. 1 illustrates concentrator solar cell 1 that is surface-mounted on a backplane or other supporting substrate 4. A top electrode or grid 7 on the light receiving surface of the solar cell 1 is electrically connected to conductive elements (for example, contact pads and/or metal (e.g., copper) traces) on the backplane by utilizing a conductive through-wafer via 5 (also referred to as a through-substrate interconnect or through-substrate via (TSV)) that extends through the solar cell from a mounting surface adjacent to the substrate 4 to the light receiving surface 9 opposite the substrate.

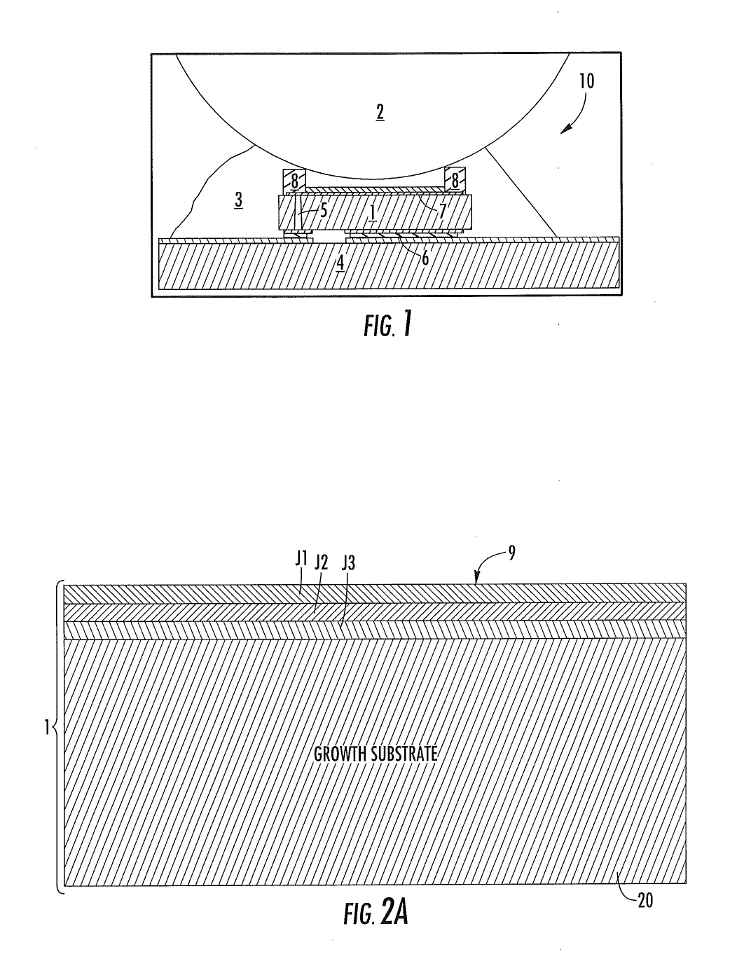

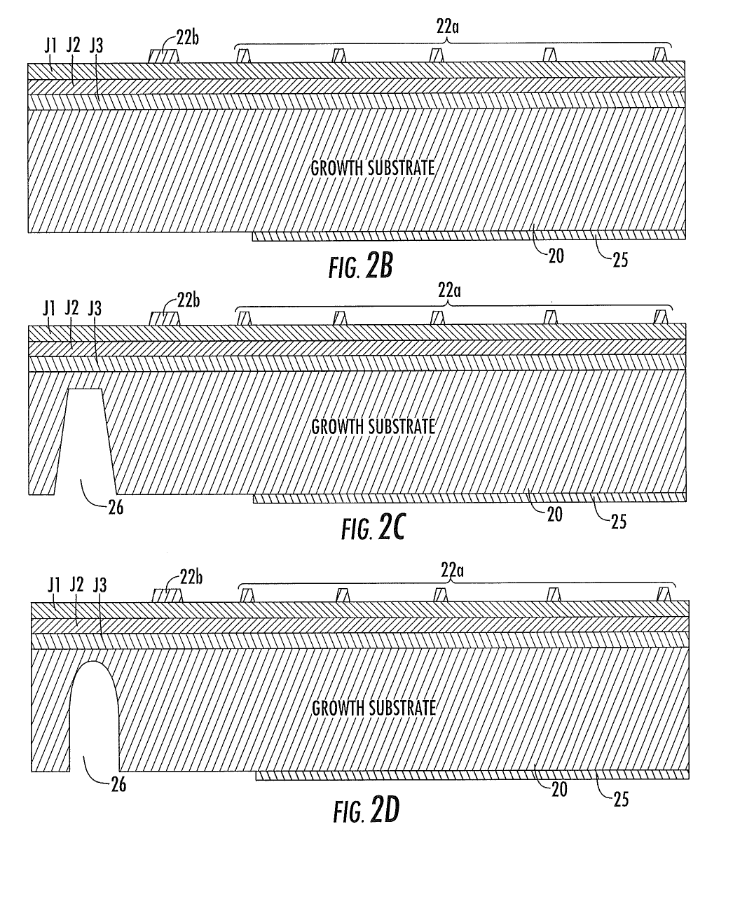

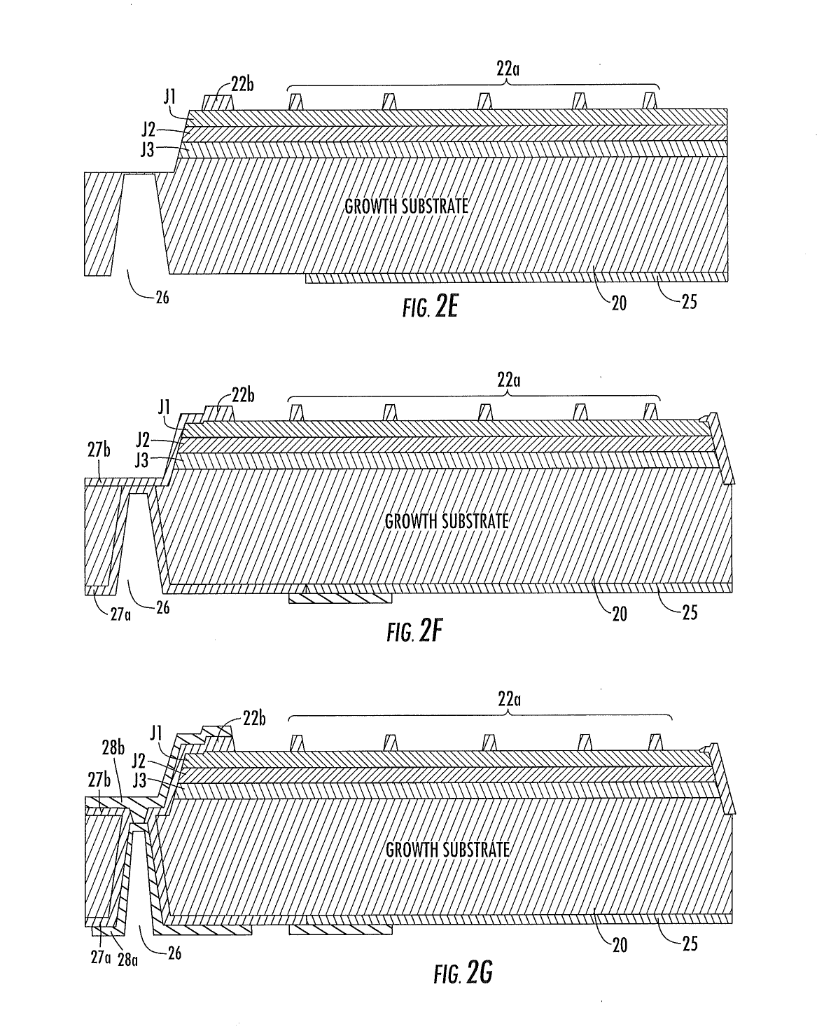

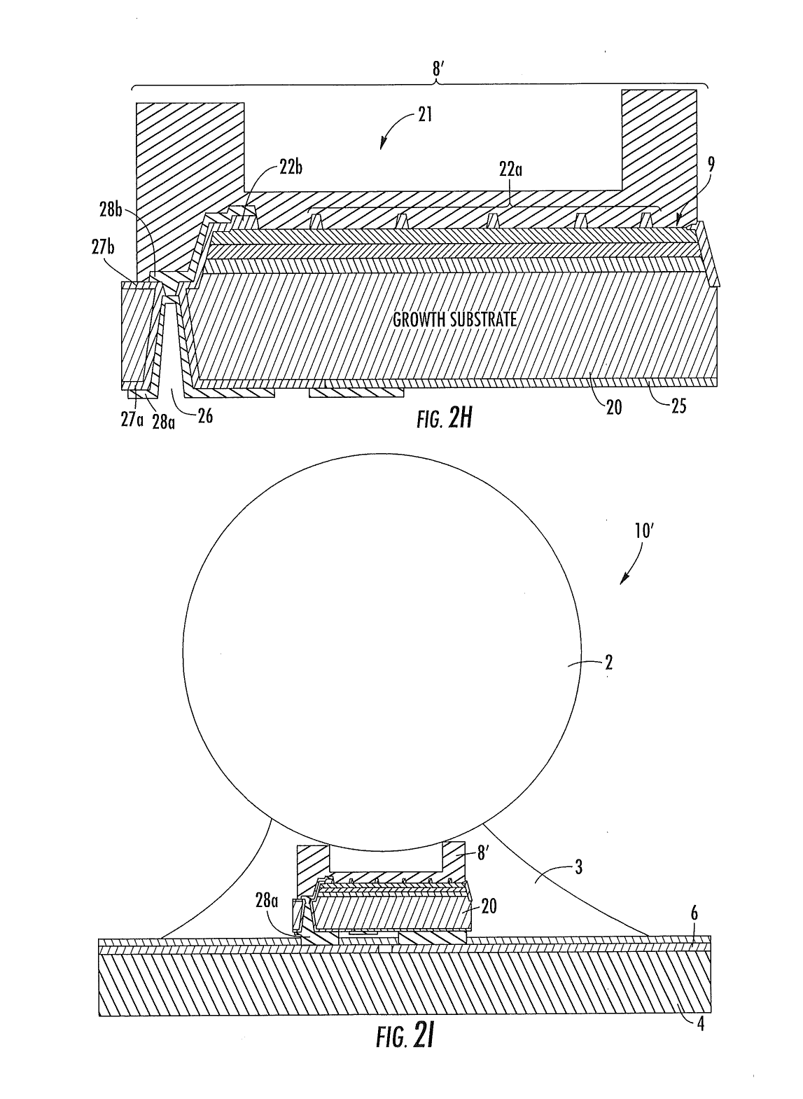

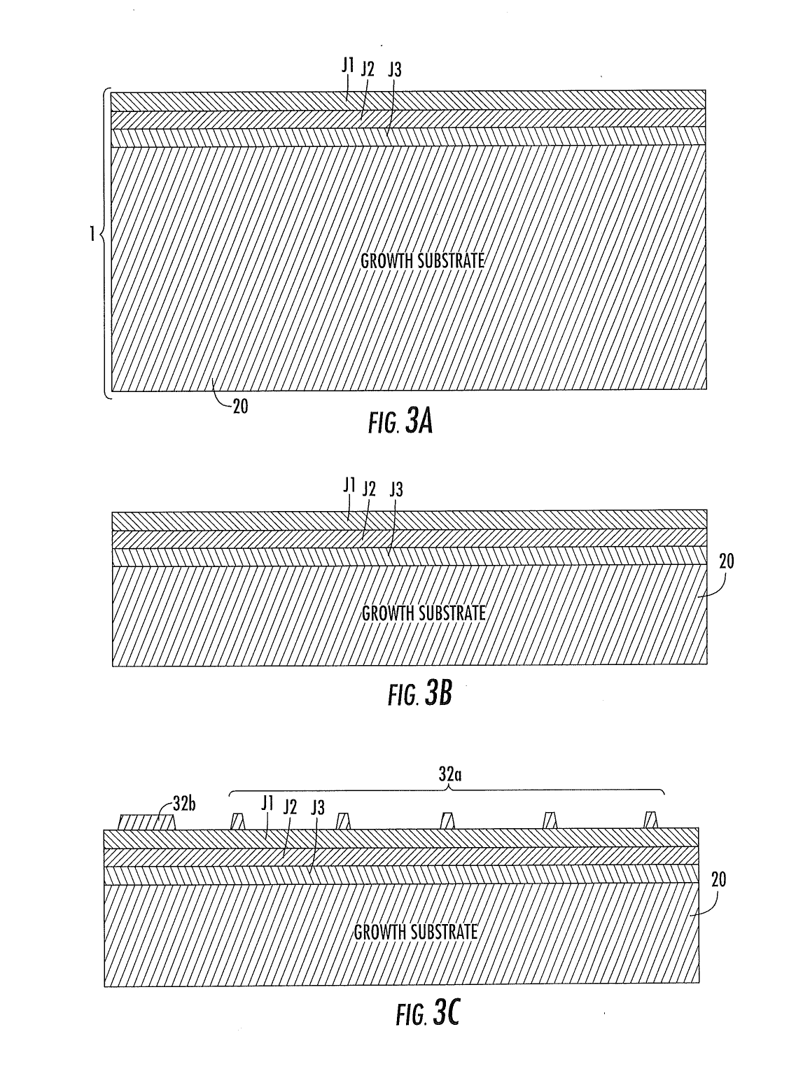

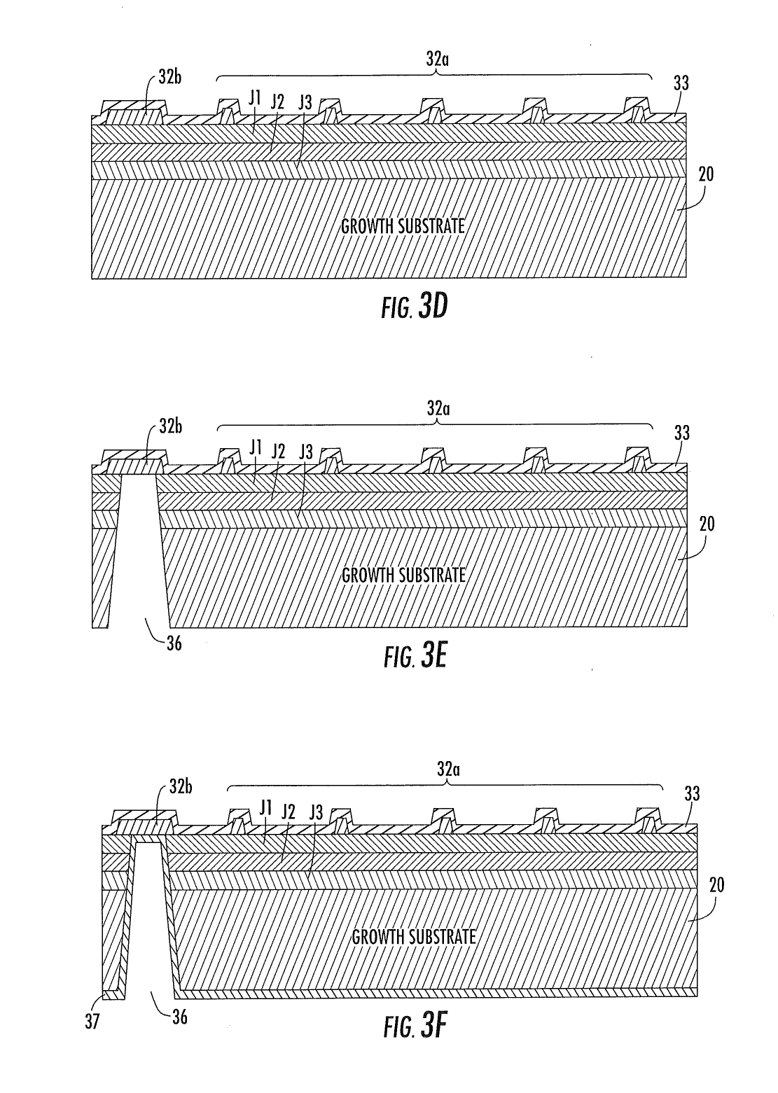

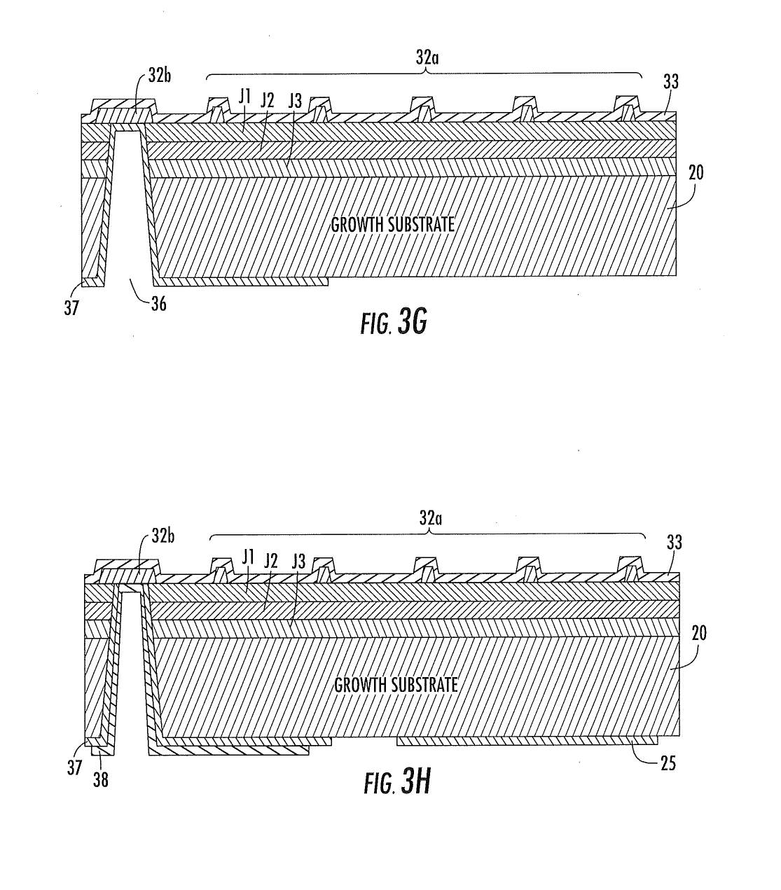

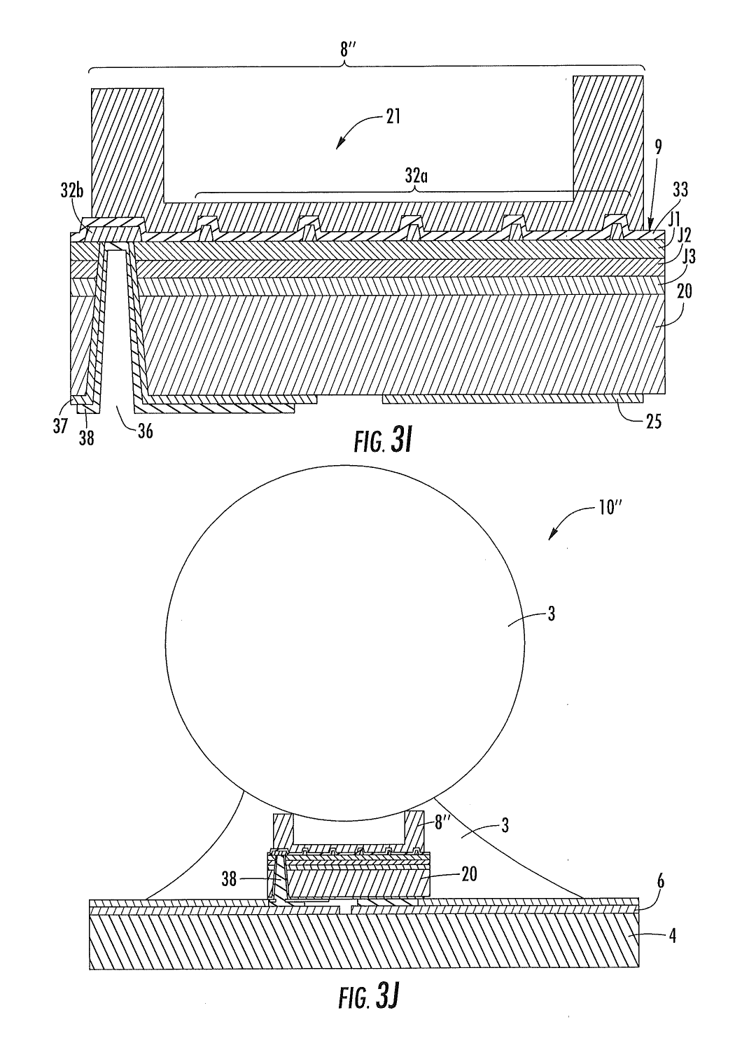

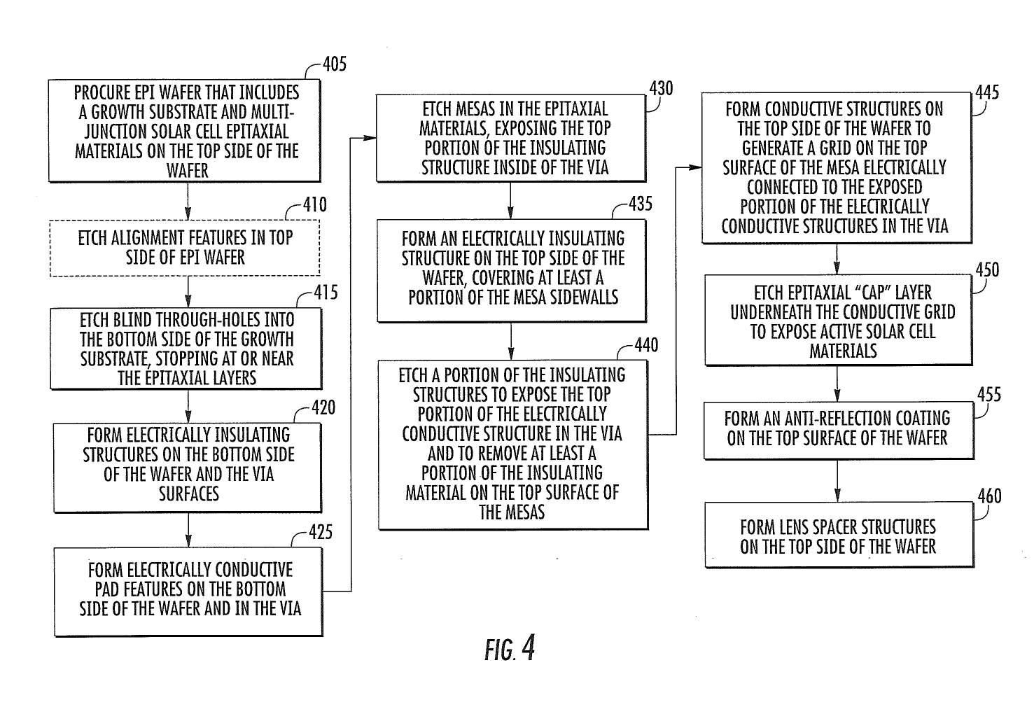

More specifically, FIG. 1 illustrates a surface-mountable, multi junction concentrator solar cell 1 that includes one or more through-wafer vias 5 to electrically connect the top terminal 7 of the solar cell 1 to a contact on the backplane 4 (or other interposer) in a surface mount operation. The via(s) 5 include insulated sidewalls and may extend through the growth substrate of the multi junction solar cell 1. The growth substrate of the cell 1 may be thinned (for example by back-grinding) to produce a thinner cell, as further illustrated in FIGS. 2B and 3B.

A solder interconnection 6 electrically connects the via 5 to the contact on the substrate 4. In some embodiments, the cell 1 is configured to be self-aligned by solder reflow to provide spatial registration between features on the backplane 3, features on the solar cell 1, and features of the lens cradle 8 discussed below. A solder mask may be used to guide the spatial positions of components during reflow of the solder interconnection 6 in some embodiments.

Still referring to FIG. 1, the CPV device 10 also includes one or more precisely positioned lens cradle structures 8, also referred to herein as lens support structures. In particular, a mechanical cradle 8 on the light receiving surface of the solar cell 1 supports and self-aligns a lens element 2 (illustrated as a spherical or ball lens by way of example) relative to the light receiving surface of the solar cell 1 to concentrate light thereon. The shape of the cradle structure 8 may depend on the shape of the lens element 2 and/or the shape of the light receiving surface 9 of the solar cell 1, and may include any shape that supports and aligns the lens element 2 with the light receiving surface 9 of the solar cell. For example, the cradle structure may have a polygonal or ellipsoidal shape, and may include a polygonal- or ellipsoidal-shaped cavity or depression that is defined by sidewalls thereof, such as a square-shaped cradle with a square- or circular-shaped cavity extending partially or completely therethrough.

In some embodiments, the cradle structures 8 may include a photo-definable material such as dry film resists Vacrel, WBR, PerMX, or photo-definable photoresists such as polyimides, silicones, or SU-8. In some embodiments, the cradle structures 8 may include precision molded materials such as silicone materials. In some embodiments, the cradle structures may include plated metal structures, e.g., copper or nickel. As such, the lens structure 8 may be fabricated on the light receiving surface of the solar cell 1, rather than being surface mounted to the cell 1 in a subsequent and/or separate process. The cradle structure 8 may be defined with a high aspect ratio, for example, such that a width of the structure 8 is less than a height of the structure 8.

In particular embodiments, the cradle structure 8 is composed of materials that are substantially optically transparent to sunlight or other light of wavelengths that may be efficiently converted by the cells, so as to reduce or prevent obstruction of the incident light. For example, the cradle structure 8 may be formed of SU-8, PerMX, and/or transparent silicones in some embodiments. However, it will be understood that embodiments of the present invention are not limited to such transparent cradle structures, and may also include at least partially opaque cradle structures. An optically transparent material 3 may be used to encapsulate the cell 1 and bond the lens element 2 to the solar cell 1 and related components. The lens element 2 may be a secondary lens element, and a primary lens element (for example, a Fresnel lens, a plano-convex lens, a double-convex lens, a crossed panoptic lens, and/or arrays thereof) may be positioned over the secondary lens element to direct incident light thereto.

FIGS. 2A-2I are cross-sectional views illustrating operations for fabricating a lens cradle and through-substrate interconnection structure in accordance with some embodiments of the present invention. Referring now to FIG. 2A, three light reactive layers are epitaxially grown on a wafer or growth substrate 20 to define the solar cell 1. As such, the solar cell 1 includes three junction layers J1, J2, and J3 (also referred to herein as sub-cells), each of which is reactive to different wavelengths of light. The different sub-cells or junction layers J1, J2, and J3 can be grown using MOCVD or MBE. However, it will be understood that while three layers or sub-cells are illustrated, the solar cell may include fewer or more (for example, four or five) sub-cells in some embodiments. Also, although illustrated with reference to fabrication of through-substrate interconnects in the growth substrate, it will be understood that the epitaxial layers J1, J2, and J3 may be first transferred to a carrier substrate, and fabrication processes described herein may be applied to the carrier substrate to define the through-substrate interconnects therein in some embodiments.

As shown in FIG. 2B, the growth substrate 20 is thinned, for example, using techniques such as grinding and dry polishing. The thinning operations may be followed by a stress relief step such as wet etching or chemical mechanical polishing. A topside metallization layer is formed on the uppermost sub-cell J1. The topside metallization layer may include a conductive grid 22a and/or one or more conductive landing pads 22b to be electrically connected to the conductive vias described herein. A bottom side metallization layer 25 is also formed on the mounting surface of the growth substrate 20, and a high temperature anneal is performed.

FIG. 2C illustrates formation of a backside via hole or opening 26 in the growth substrate 20. The backside via hole 26 may be formed by wet etching and/or plasma etching (ICP RIB, etc.) in some embodiments. For example, a frontside protection layer (such as a metal, dielectric, and/or organic layer) may be formed on the surface of layer J1. A photoresist may be patterned on the backside of the growth substrate 20 using a photolithography process. An etching into the growth substrate 20 (such as a timed etch) may then be performed, for example, using an inductively couple plasma (ICP) reactive ion etcher (RIE) to define the via hole 26. The photoresist may be removed, and the frontside protection layer may be removed.

FIG. 2D further illustrates formation of the backside via hole 26. In particular, as shown in FIG. 2D, the backside via hole 26 formed in FIG. 2C may, in some embodiments, be laser drilled, water jet drilled, grit blasted, etc., to round or otherwise reduce the sharpness of the via hole 26 resulting from the etching processes of FIG. 2C.

FIG. 2E illustrates processing of the growth substrate 20 such that the backside via hole 26 extends completely therethrough from a mounting surface opposite the junction layers J1, J2, and J3 to the light receiving surface 9 including the layers J1, J2, and J3 thereon. In particular, as shown in FIG. 2E, a mesa patterning and etching process is performed to reveal or expose the backside via hole or opening 26 at the light receiving surface 9 of the growth substrate 20.

FIG. 2F illustrates formation of a sidewall dielectric layer 27a on the sidewalls of the backside via hole or opening 26 to provide insulation from the growth substrate 20. More particularly, as shown in FIG. 2F, a dielectric or other insulating layer 27a is formed on the inner sidewalls of the via hole 26. The dielectric or other insulating layer 27b may also be formed on portions of the light reactive layers J1, J2, and/or J3 on the light receiving surface of the growth substrate 20.

FIG. 2G illustrates formation of a thin-film metallization layer to provide a through-substrate interconnect 28a in the backside via hole 26 that electrically contacts the conductive grid 22a and/or one or more conductive landing pads 22b on the topside/light receiving surface. As further shown in FIG. 2G, a metallization layer 28b extends through the dielectric layer 27a, 27b formed in FIG. 2F to provide an electrical connection between the leftmost conductive terminal 22b and the through-substrate interconnect 28a

FIG. 2H illustrates formation of a lens cradle structure 8′ in accordance with some embodiments of the present invention, similar to the lens cradle 8 of FIG. 1. In particular, FIG. 2H illustrates a molded silicone cradle structure 8′ that is formed on the light receiving surface 9 of the solar cell 1. The silicone cradle structure 8′ includes an opening or cavity 21 that is aligned with the light receiving surface 9 of the solar cell 1. The shape of the cradle structure 8′ may depend on the shape of the lens element 2; for example, the cradle structure 8′may have a polygonal or ellipsoidal shape, and may include a polygonal- or ellipsoidal-shaped cavity or depression 21 that is defined by sidewalls thereof. The opening 21 may or may not extend completely through the cradle structure 8′, depending for example on the transparency of the cradle structure 8′, such that a transparent cradle structure may cover a majority or all of the light receiving surface 9 in some embodiments. The cradle structure 8′ may have a high aspect ratio, for example, having a width less than a height thereof. The cradle structure 8′ may be transparent to allow incident light (for example, having wavelengths corresponding to the light reactive layers of the sub-cells J1, J2, and/or J3) to pass therethrough without obstruction. As such, the cradle structure 8′ may be fabricated directly on the solar cell 1. Although illustrated in FIG. 2H as a substantially transparent silicone structure, it will be understood that the cradle structure 8′ may be formed of other and/or opaque materials in some embodiments. Singulation of the wafer/growth substrate 20 may also be performed to separate the wafer/substrate 20 into a plurality of solar cells, for example, using a laser and/or a dicing saw, such that each singulated solar cell 1 includes a respective lens cradle structure 8′ thereon.

FIG. 2I illustrates a completed CPV receiver 10′ in accordance with some embodiments. In particular, as shown in FIG. 21, each solar cell 1 (including the respective lens cradle structure 8′ thereon) is provided on a backplane or other support substrate 4 using pick-and-place techniques. A solder reflow process is performed to self-align each solar cell 1, thereby providing spatial registration between features on the backplane 4, features on the solar cell 1, and/or features of the lens cradle 8′. A silicone under-fill is performed to encapsulate the cell 1 with an optically-transparent material 3, and the spherical lens element 2 is placed on each lens cradle structure 8′. The protruding features of the lens cradle structures 8′ support and self-align the respective spherical lens elements 2 to provide an array of concentrator-type CPV receivers 10′. In some embodiments, the spherical lens elements 2 may be secondary lens elements, and a primary lens element (for example, a Fresnel lens, a plano-convex lens, a double-convex lens, a crossed panoptic lens, and/or an array thereof) may be provided over the backplane 4 to direct light toward the respective secondary lens elements 2. While illustrated as a spherical lens element 2, it will be understood that lens elements of other shapes may also be used in some embodiments.

FIGS. 3A-3J are cross-sectional views illustrating operations for fabricating a lens cradle and through-substrate interconnection structure in accordance with further embodiments of the present invention.

FIG. 3A illustrates epitaxial growth of a solar cell on a growth substrate. Referring now to FIG. 3A, three light reactive layers are epitaxially grown on a wafer or growth substrate 20 to define the solar cell 1. As such, the solar cell 1 includes three junction layers J1, J2, and J3 (also referred to herein as sub-cells), each of which is reactive to different wavelengths of light. The different sub-cells or junction layers J1, J2, and J3 can be grown using MOCVD or MBE. However, it will be understood that while three layers or sub-cells are illustrated, the solar cell may include fewer or more (for example, four or five) sub-cells in some embodiments. Also, although illustrated with reference to fabrication of through-substrate interconnects in the growth substrate 20, it will be understood that the layers J1, J2, and J3 may be transferred to a carrier substrate different than the growth substrate prior to performing the through-substrate interconnect fabrication processes described herein, such that the through substrate interconnects instead extend through/between opposing surfaces of the carrier substrate.

As shown in FIG. 3B, the growth substrate 20 is thinned, for example, using techniques such as grinding and dry polishing. The thinning operations may be followed by a stress relief step such as wet etching or chemical mechanical polishing.

FIG. 3C illustrates fabrication of a frontside metallization layer. As shown in FIG. 3C, the frontside metallization layer is formed on the uppermost sub-cell J1 and patterned to define a conductive grid 32a and/or one or more conductive landing pads 32b for the conductive vias described herein. FIG. 3D illustrates deposition of anti-reflection coating 33 on the patterned metallization layer 32a, 32b.

FIG. 3E illustrates fabrication of a backside via hole or opening 36 extending through the growth substrate 20 to provide contact to one or more of the landing pads 32b of the topside metallization layer. The backside via hole 36 may be formed by wet etching and/or plasma etching (ICP RIE, etc.) in a manner similar to that described above with reference to FIG. 2C.

FIG. 3F illustrates deposition of backside dielectric layer 37 on the sidewalls of the backside via hole 36 to provide insulation from the growth substrate 20. More particularly, as shown in FIG. 3F, a dielectric or other insulating layer 37 is formed on the inner sidewalls of the via hole 36. FIG. 3G illustrates patterning of the backside dielectric layer 37. In particular, as shown in FIG. 3G, portions of the dielectric layer 37 at the “bottom” of the via hole 36 (relative to the opening in the backside of the growth substrate 20) are selectively etched to expose the leftmost conductive terminal 32b.

FIG. 3H illustrates deposition of backside metallization layer to provide a through-substrate interconnect 38 in the backside via hole 36 that electrically contacts the conductive grid 32a and/or one or more conductive landing pads 32b on the topside/light receiving surface 9 to a contact on the mounting surface of the growth substrate.

FIG. 3I illustrates fabrication of a lens cradle structure 8″ in accordance with some embodiments of the present invention, similar to the lens cradle 8 of FIG. 1. In particular, FIG. 3I illustrates a molded silicone cradle structure 8″ that is fabricated on the light receiving surface of the solar cell 1. The cradle structure 8″ may include any shape that supports and aligns the lens element 2 with the light receiving surface 9 of the solar cell. The silicone cradle structure 8″ includes an opening or cavity 21 therein that is aligned with the light receiving surface 9 of the solar cell 1. The cradle structure 8″ may have a high aspect ratio, for example, having a width less than a height thereof, and may be substantially transparent to allow incident light (for example, having wavelengths corresponding to the light reactive layers of the sub-cells J1, J2, and/or J3) to pass therethrough without obstruction. Thus, the cradle structure 8″ may be formed directly on the solar cell 1. Although illustrated in FIG. 3I as a substantially transparent silicone structure, it will be understood that the cradle structure 8″ may be formed of other and/or opaque materials in some embodiments. Singulation of the wafer/growth substrate 20 may also be performed to separate the wafer/substrate 20 into a plurality of solar cells, for example, using a laser and/or a dicing saw. Each singulated solar cell 1 thus includes a respective lens cradle structure 8″ thereon.

FIG. 3J illustrates a completed CPV receiver 10″ in accordance with further embodiments. In particular, as shown in FIG. 3J, each solar cell 1 (including the respective lens cradle structure 8″ thereon) is provided on a backplane or other support substrate 4 using pick-and-place techniques. A solder reflow process is performed to self-align each solar cell 1, thereby providing spatial registration between features on the backplane 4, features on the solar cell 1, and/or features of the lens cradle 8″. A silicone under-fill is performed to encapsulate the cell with an optically-transparent material 3, and the spherical lens element 2 is placed on each lens cradle structure 8″. The protruding features of the lens cradle structures 8″ support and self-align the respective spherical lens elements 2 to provide an array of concentrator-type CPV receivers 10″. In some embodiments, the spherical lens elements 2 may be secondary lens elements, and a primary lens element (for example, a Fresnel lens, a plano-convex lens, a double-convex lens, a crossed panoptic lens, and/or an array thereof) may be provided over the backplane 4 to direct light toward the respective secondary lens elements 2. Lens elements of other shapes may also be used in some embodiments.

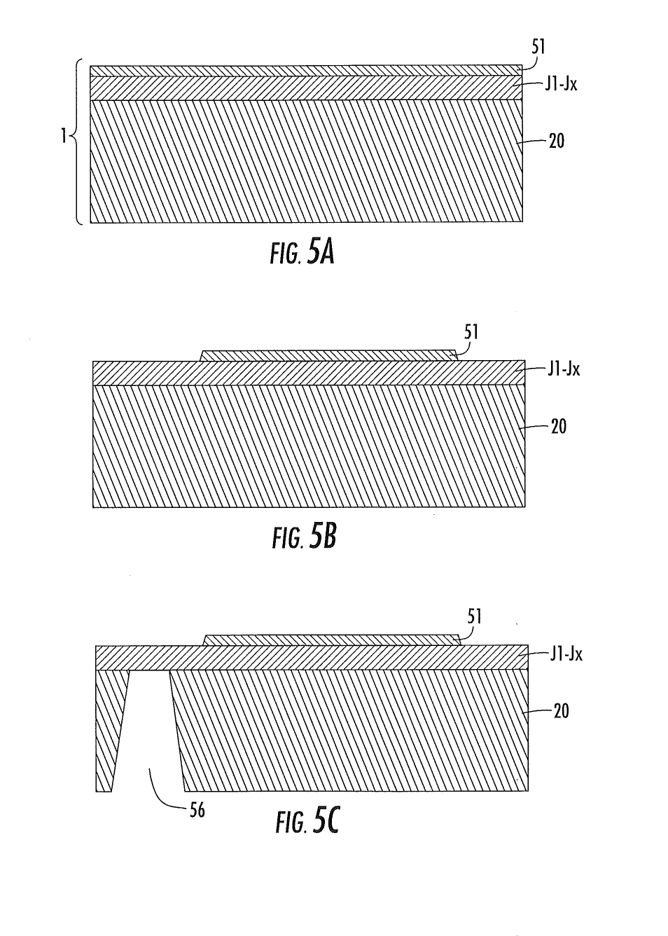

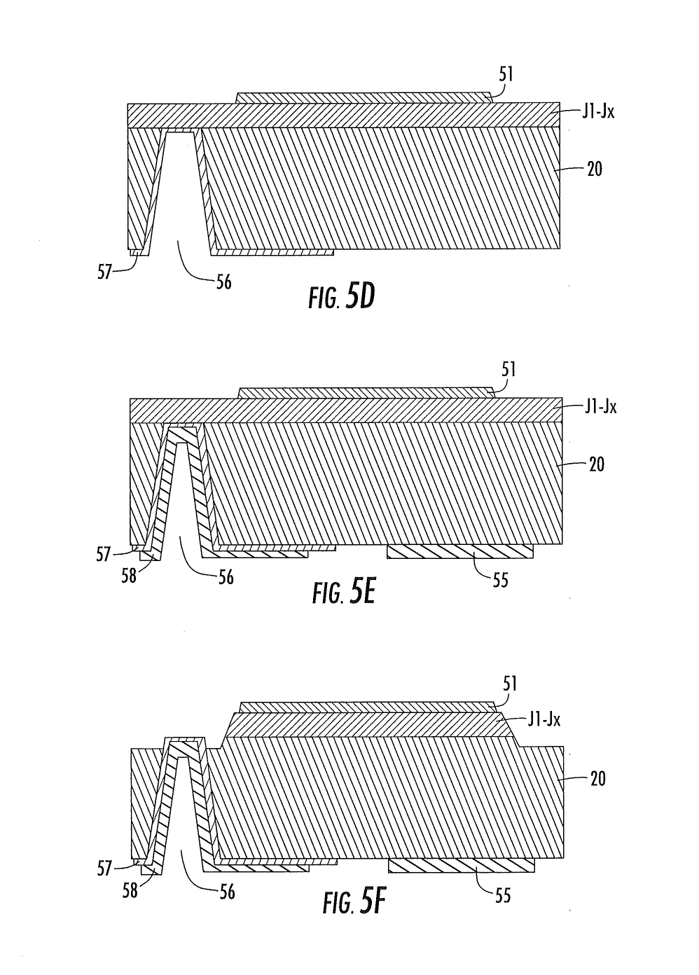

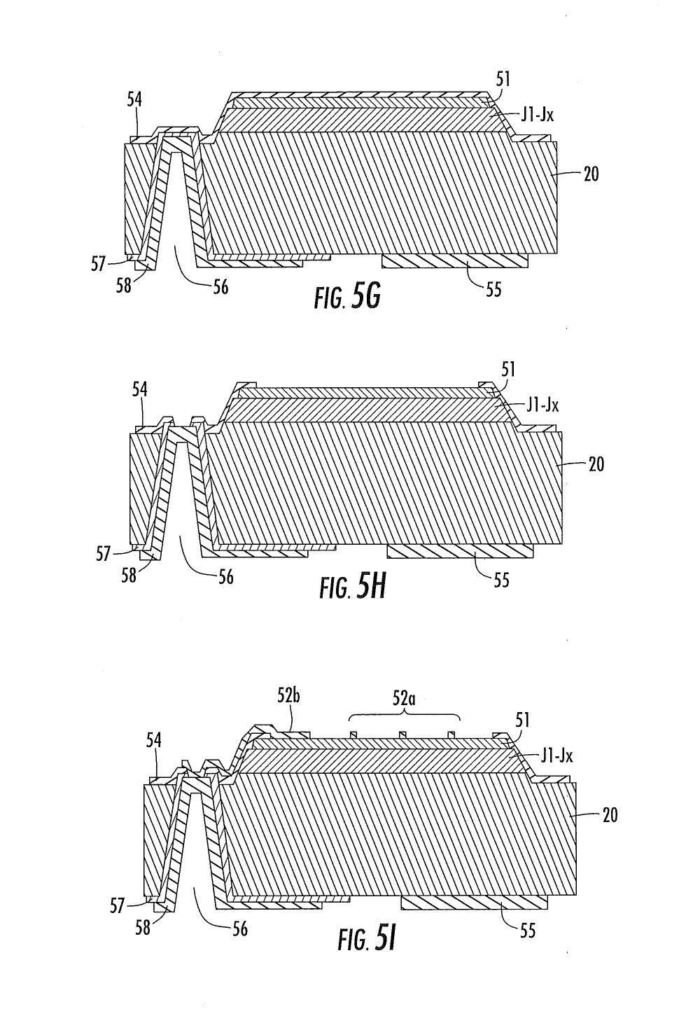

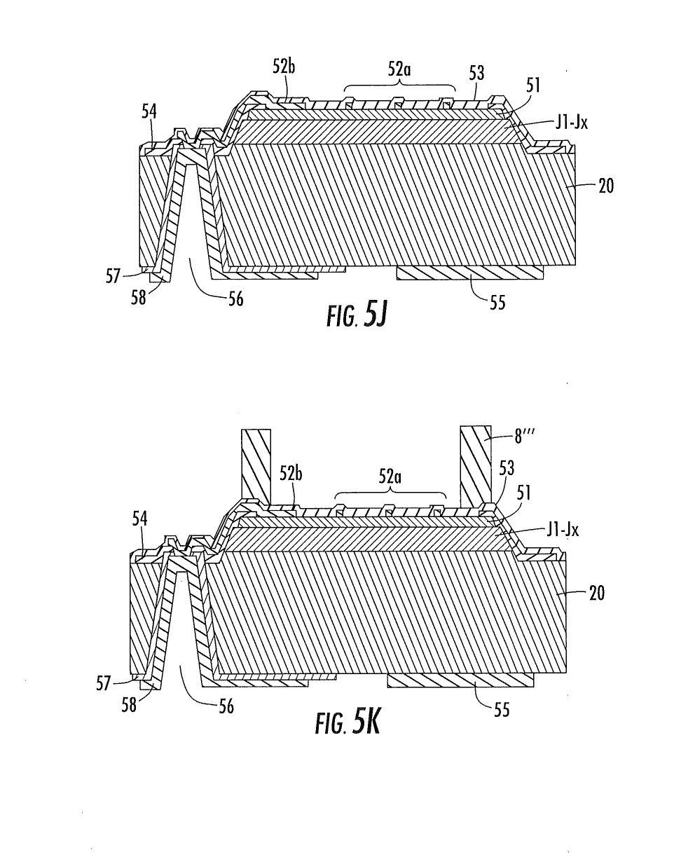

FIG. 4 is a flowchart illustrating operations for fabricating a lens cradle and through-substrate interconnection structure in accordance with further embodiments of the present invention. FIGS. 5A-5K are cross-sectional views illustrating the operations of FIG. 4.

Referring now to FIGS. 4 and 5A, a wafer or substrate 20 and multi junction solar cell epitaxial material layers J1-Jx on the top side of the substrate 20 is procured or otherwise provided, as shown at block 405. In some embodiments, the substrate 20 may be an epi wafer or other growth substrate, and the layers J1-Jx may be epitaxially grown on the growth substrate. In other embodiments, the substrate 20 may be a carrier substrate, and the epitaxial material layers J1-Jx may be grown on a different substrate and transferred to the substrate 20.

FIG. 5B illustrates the etching of alignment features 51 on a top side of the substrate 20, as shown at block 410. In FIG. 5C, blind through-holes 56 are etched into the bottom side of the substrate 20, stopping at or near the epitaxial layers J1-Jx, as shown at block 415.

FIG. 5D illustrates formation of electrically insulating structures 57 on the bottom side of the substrate 20 and sidewall surfaces of the via hole 56, as shown at block 420. In FIG. 5E, electrically conductive pad features 55 are formed on the bottom side of the substrate 20, and an electrically conductive through-substrate interconnect 58 is formed in the via hole 56, as shown at block 425. The pad features 55 and the interconnect 58 may be formed from a same layer or process step in some embodiments.

FIG. 5F illustrates etching of the epitaxial material layers J1-Jx to define mesas, thereby exposing the top portion of the insulating structure 57 inside the via hole 56, as shown at block 430. In FIG. 5G, an electrically insulating structure 54 is formed on the top side of the substrate 20, covering at least a portion of the mesa sidewalls, as shown at block 435.

FIG. 5H illustrates etching of a portion of the insulating structures 54, 57 to expose the top portion of the electrically conductive interconnect 58 in the via hole 56 and to remove at least a portion of the insulating material 54 on the top surface of the mesas, as shown at block 440. In FIG. 51 conductive structures 52a, 52b are formed on the top side of the substrate 20 to generate a grid 52a on the top surface of the mesa. The grid 52a is electrically connected to the exposed portion of the electrically conductive interconnect 58 in the via hole 56 by the conductive structure 52b, as shown at block 445. FIG. 5I also illustrates etching of an epitaxial “cap” layer underneath the conductive grid 52a to expose active solar cell materials, as shown at block 450.

FIG. 5J illustrates formation of an anti-reflective coating 53 on the top surface of the substrate 20, as shown at block 455. FIG. 5K illustrates formation of lens support structures 8′″ on the top side of the wafer at block 460. The lens support structure 8′″ may be similar in shape and/or material to the lens support structure 8 of FIG. 1. As such, the lens support structure 8′″ may include a photo-definable material (such as dry film resists Vacrel, WBR, PerMX, or photo-definable photoresists such as polyimides, silicones, or SU-8), precision molded materials (such as silicone materials), and/or plated metal structures (such as copper or nickel), and may include any shape that is configured to support and align a lens element (for example, a spherical ball or other-shaped lens element) as described herein.

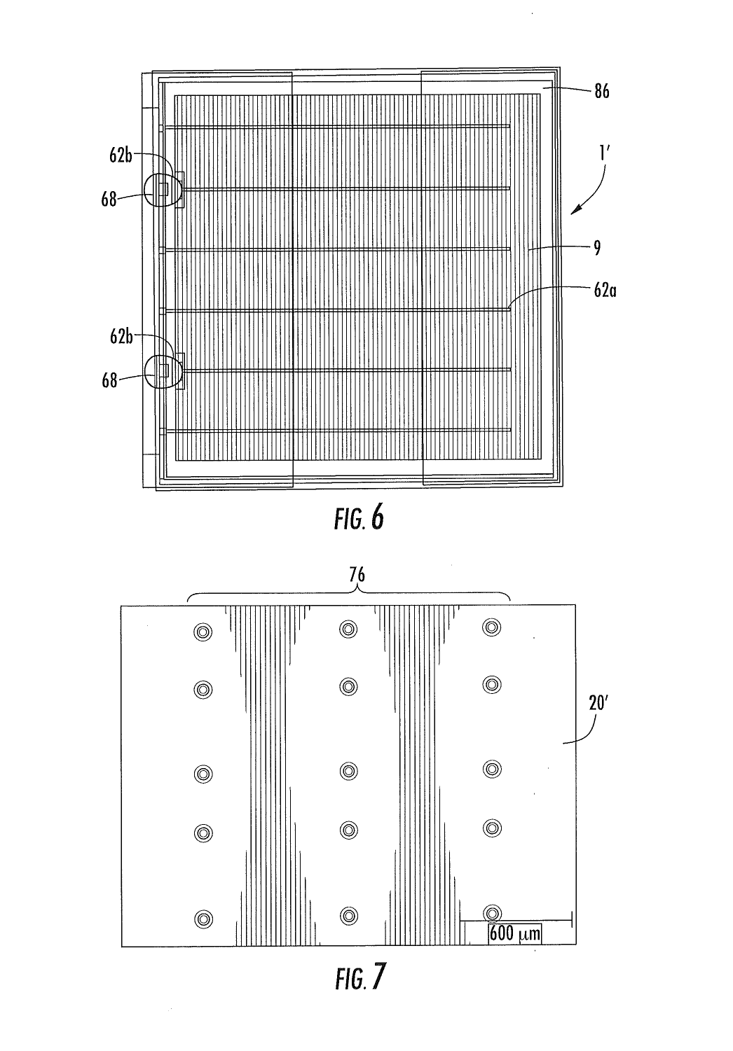

FIG. 6 is a plan view illustrating a layout of a solar cell 1′ in accordance with some embodiments of the present invention. Referring now to FIG. 6, the solar cell 1′ includes through-substrate vias 68 that extend through a substrate 20 to provide electrical connection between conductive pads 62b and/or conductive grid 62a on a light receiving surface 9 and one or more conductive elements on a mounting surface opposite to the light receiving surface 9. The solar cell 1′ also includes a square-shaped lens support structure 86 on the light receiving surface 9, which is configured to support and align a lens element (such as a ball lens 2 described above) to concentrate incident light on the light receiving surface 9. The lens support structure 86 may be similar in shape/materials to those described above and/or formed using any of the methods described herein.

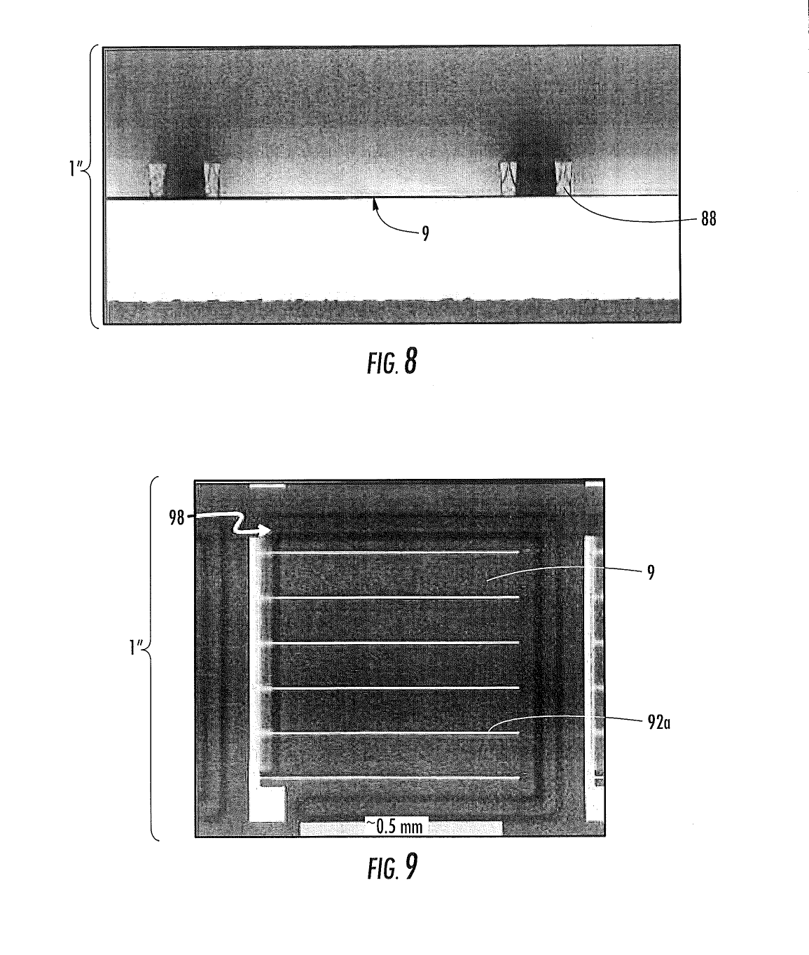

FIG. 7 is a plan view illustrating an example array of via holes 76 formed in accordance with some embodiments of the present invention. The via holes 76 shown in FIG. 7 were etched through a germanium growth wafer 20′. The via holes 76 were etched using a repeated sequence of reactive ion etching and sidewall passivation, also known as a Bosch Process. The via holes 76 extend from the bottom side of the wafer 20′ to epitaxial layers that were grown on the top side of the wafer 20′.

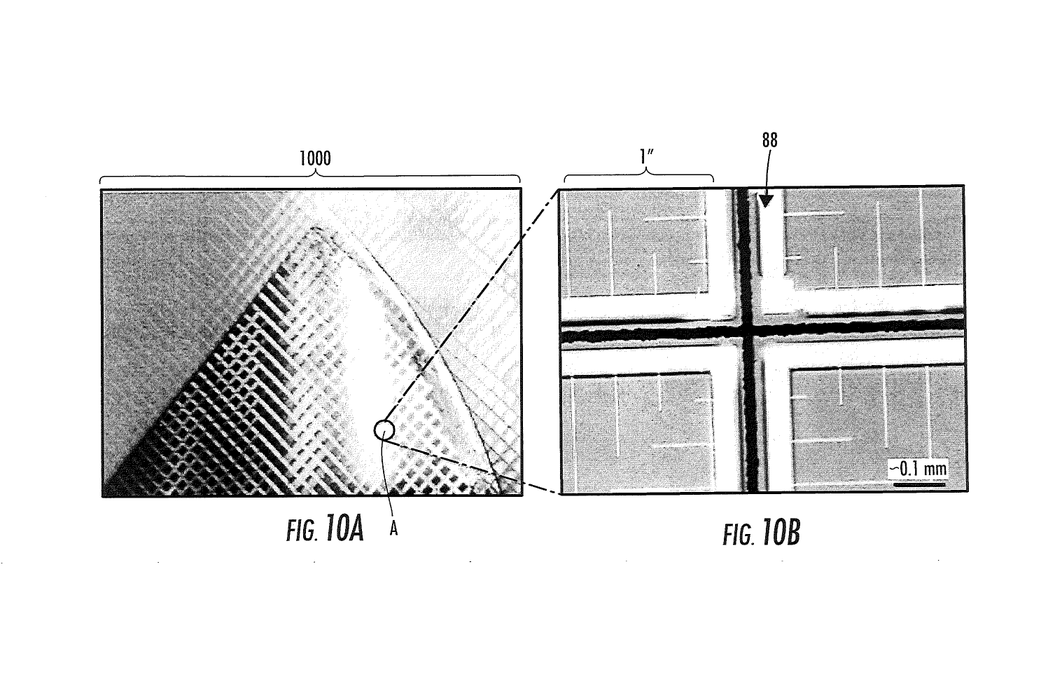

FIG. 8 is a cross-sectional micrograph illustrating lens support structures 88 in accordance with some embodiments of the present invention. As shown in FIG. 8, the lens support structures 88 are formed of a photo-definable epoxy on a light receiving surface 9 of a solar cell 1″. The lens support structures 88 may be similar in materials and/or fabrication as those described herein with respect to the embodiments of FIGS. 1-7. However, in the embodiment of FIG. 8 (as well as in the embodiments of FIGS. 9-11 discussed below), the solar cell 1″ does not include the through-substrate interconnects of FIGS. 1-7 extending therethrough.

FIG. 9 is a plan view illustrating a partially formed solar cell 1″ in accordance with some embodiments of the present invention. Referring now to FIG. 9, the solar cell 1″ includes a lens support structure 98 on a light receiving surface 9, which also includes conductive traces 92a thereon. The lens support structure 98 is configured to support and align a lens element (such as a ball lens 2 described above) to concentrate incident light on the light receiving surface 9. The illustrated lens support structure 98 has a partial square-shape and is made of photo-definable epoxy, but may be formed of other materials/shapes and/or in a manner similar as those described above. Singulation (for example, by dicing) completes the fabrication of the solar cell 1″,

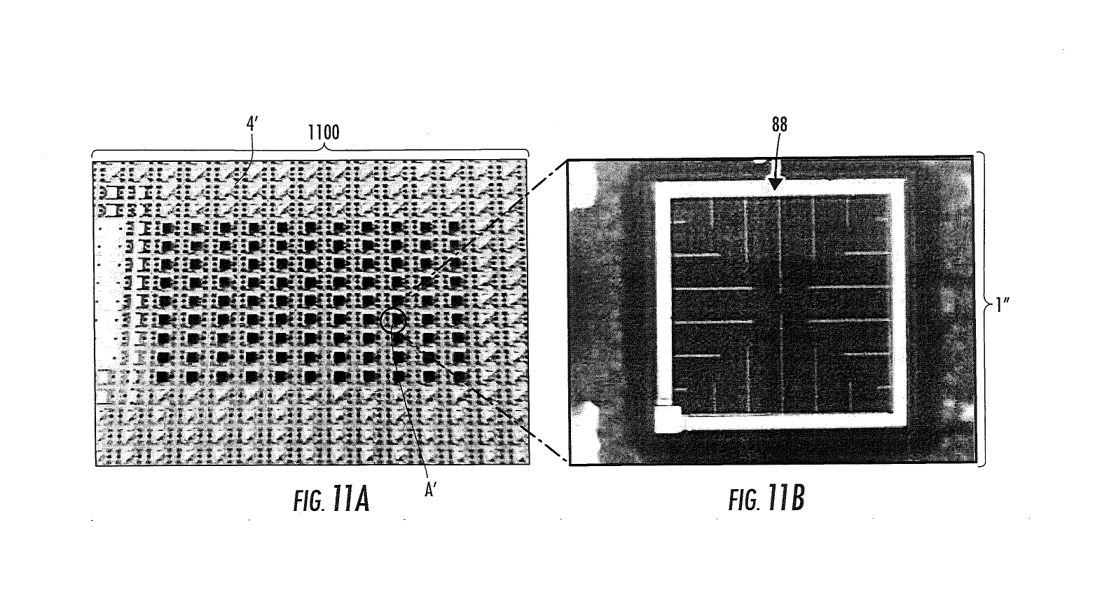

FIG. 10A is a photograph illustrating an array 1000 of solar cells 1″ including lens support structures 88 in accordance with some embodiments of the present invention after singulation by saw dicing. FIG. 10B illustrates an enlarged view of portion A shown in FIG. 10A. In FIGS. 10A-10B, the cells 1″ of the array 1000 include a square-shaped lens support structures 88 made of photo-definable epoxy.

FIG. 11A is a photograph illustrating an array 1100 of solar cells 1″ including lens support structures 88 in accordance with further embodiments of the present invention. In FIG. 11A, the cells 1″ are surface-mounted to a ceramic interposer 4′ using lead-free solder. FIG. 11B illustrates an enlarged view of portion A′ of FIG. 11A. In FIGS. 11A-11B, the cells 1″ in the array 1100 include lens support structures 88 having sidewalls that define a square shape and formed from a photo-definable epoxy. However, it will be understood that the lens support structures 88 illustrated in FIGS. 8-11 may be formed of other materials and/or using any fabrication methods described herein. Moreover, while primarily illustrated herein as having square-shaped sidewalls, the lens support structures described herein may include any shape that supports and aligns the lens element with a light receiving surface of a solar cell, including polygonal or ellipsoidal shaped-sidewalls, and/or polygonal- or ellipsoidal-shaped cavities or depressions defined by the sidewalls thereof.

The present invention has been described above with reference to the accompanying drawings, in which embodiments of the invention are shown. However, this invention should not be construed as limited to the embodiments set forth herein. Rather, these embodiments are provided so that this disclosure will be thorough and complete, and will fully convey the scope of the invention to those skilled in the art. In the drawings, the thickness of layers and regions are exaggerated for clarity. Like numbers refer to like elements throughout.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. In no event, however, should “on” or “directly on” be construed as requiring a layer to cover an underlying layer.

It will also be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present invention.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower”, can therefore, encompasses both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

The terminology used in the description of the invention herein is for the purpose of describing particular embodiments only and is not intended to be limiting of the invention. As used in the description of the invention and the appended claims, the singular forms “a”, “an ” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, the regions illustrated in the figures are schematic in nature and their shapes are not intended to illustrate the actual shape of a region of a device and are not intended to limit the scope of the invention.

Unless otherwise defined, all terms used in disclosing embodiments of the invention, including technical and scientific terms, have the same meaning as commonly understood by one of ordinary skill in the art to which this invention belongs, and are not necessarily limited to the specific definitions known at the time of the present invention being described. Accordingly, these terms can include equivalent terms that are created after such time. It will be further understood that terms, such as those defined in commonly used dictionaries, should be interpreted as having a meaning that is consistent with their meaning in the present specification and in the context of the relevant art and will not be interpreted in an idealized or overly formal sense unless expressly so defined herein. All publications, patent applications, patents, and other references mentioned herein are incorporated by reference in their entireties.

Many different embodiments have been disclosed herein, in connection with the above description and the drawings. It will be understood that it would be unduly repetitious and obfuscating to literally describe and illustrate every combination and subcombination of these embodiments. Accordingly, the present specification, including the drawings, shall be construed to constitute a complete written description of all combinations and subcombinations of the embodiments described herein, and of the manner and process of making and using them, and shall support claims to any such combination or subcombination.

In the specification, there have been disclosed embodiments of the invention and, although specific terms are employed, they are used in a generic and descriptive sense only and not for purposes of limitation.

That which is claimed:

1. A concentrator-type photovoltaic (CPV) device, comprising:
a solar cell comprising a substrate including a light receiving surface having a conductive terminal thereon and a mounting surface opposite the light receiving surface;
a conductive through-substrate interconnect having insulated sidewalls extending into the substrate from the mounting surface toward the light receiving surface to electrically contact the conductive terminal;
a lens support structure on the light receiving surface; and
a lens element on the lens support structure opposite the light receiving surface, the support structure supporting and aligning the lens element with the light receiving surface.

2. The device of claim 1, wherein the solar cell comprises a multi junction device including a plurality of sub-cells on the light-receiving surface, wherein at least two of the sub-cells are reactive to a different wavelength of light.

3. The device of claim 2, wherein the through-substrate interconnect is electrically connected to one of the sub-cells but is electrically isolated from other ones of the sub-cells and the substrate.

4. The device of claim 1, wherein the lens support structure comprises an optically transparent material.

5. The device of claim 4, wherein the lens support structure covers a majority of the light receiving surface.

6. The device of claim 1, wherein the lens support structure comprises a photo-definable material, a molded material, and/or a plated metal structure.

7. The device of claim 1, wherein the lens element comprises a spherical lens element, and wherein the lens support structure includes features having widths less than respective heights thereof configured to support and self-align the spherical lens element with the light receiving surface.

8. The device of claim 1, wherein the solar cell is a surface-mountable device, wherein the mounting surface is provided on a backplane substrate, and further comprising:
a solder connection between the through-substrate interconnect adjacent the mounting surface and an electrical contact on the substrate, wherein the solar cell and the support structure thereon is configured to be self-aligned to features of the substrate by reflow of the solder connection.

9. The device of claim 1, wherein the light receiving surface has an area of about 4 mm² or less.

10. The device of claim 1, further comprising:
an anti-reflection coating between the light receiving surface of the solar cell and the lens support structure.

11. A method of fabricating a concentrator-type photovoltaic (CPV) device, the method comprising:
forming at least one light reactive layer and a conductive terminal on a light receiving surface of a substrate opposite a mounting surface thereof;
forming a conductive through-substrate interconnect having insulated sidewalls extending into the substrate from the mounting surface toward the light receiving surface to electrically contact the conductive terminal thereon;
forming a lens support structure on the light receiving surface;
singulating the substrate including the lens support structure thereon to define a solar cell; and
placing a lens element on the support structure opposite the light receiving surface, the support structure supporting and aligning the lens element with the light receiving surface.

12. The method of claim 11, wherein forming the at least one light reactive layer comprises:
epitaxially growing a plurality of light reactive layers on the light receiving surface of the substrate, wherein at least two of the light reactive layers are reactive to a different wavelength of light.

13. The method of claim 12, wherein the through-substrate interconnect is electrically connected to one of the light reactive layers but is electrically isolated from other ones of the light reactive layers and the substrate.

14. The method of claim 11, wherein forming the through-substrate interconnect comprises:
masking and etching the mounting surface to define an opening therein extending toward the light receiving surface;
forming an insulating layer on sidewalls of the opening; and
forming a conductive layer on the insulating layer in the opening,
wherein the conductive layer electrically contacts the conductive terminal.

15. The method of claim 14, wherein forming the through-substrate interconnect further comprises:
selectively etching a portion of the insulating layer between the sidewalls of the opening prior to forming the conductive layer in the opening.

16. The method of claim 15, wherein the opening in the mounting surface is aligned with the conductive terminal on the light receiving surface, and wherein selectively etching exposes a portion of the conductive terminal.

17. The method of claim 15, wherein the conductive layer comprises a first conductive layer, and further comprising:
forming a second conductive layer extending from the first conductive layer in the opening to the conductive terminal on the light receiving surface.

18. The method of claim 17, further comprising:
patterning the light receiving surface to expose the opening and to define a mesa structure including the at least one light reactive layer prior to forming the second conductive layer.

19. The method of claim 14, wherein the conductive layer comprises a first conductive layer, wherein forming the through-substrate interconnect further comprises:
selectively etching a portion of the insulating layer between the sidewalls of the opening after forming the conductive layer therein to expose the first conductive layer; and
forming a second conductive layer extending from the first conductive layer in the opening to the conductive terminal on the light receiving surface.

20. The method of claim 19, further comprising:
patterning the light receiving surface to expose the portion of the insulating layer and to define a mesa structure including the at least one light reactive layer prior to forming the second conductive layer.

21. The method of claim 11, wherein forming the lens support structure comprises curing the lens support structure on the light receiving surface, wherein the lens support structure comprises an optically transparent material.

22. The method of claim 11, further comprising the following prior to placing the lens element:
surface-mounting the solar cell on a backplane substrate such that a solder connection is provided between an electrical contact on the backplane substrate and a portion of the through-substrate interconnect adjacent the mounting surface; and
reflowing the solder connection to align the solar cell and the support structure thereon with features of the backplane substrate.

23. A method of fabricating a concentrator-type photovoltaic (CPV) device, the method comprising:
forming a lens support structure on a light receiving surface of a solar cell on a substrate using a photolithography process, a molding process, and/or a plating process; and
placing a lens element on the lens support structure opposite the light receiving surface.

24. The method of claim 23, further comprising:
singulating the substrate including the lens support structure thereon prior to providing the lens element on the lens support structure.

25. The method of claim 24, wherein the lens support structure comprises an optically transparent material.

26. The method of claim 25, wherein the lens support structure is formed to cover a majority of the light receiving surface.

27. A method of fabricating a photovoltaic device, the method comprising:
epitaxially growing a plurality of light reactive layers on a light receiving surface of a substrate opposite a mounting surface thereof, wherein at least two of the light reactive layers are reactive to a different wavelength of light;
forming a conductive terminal on the light receiving surface; and
forming a conductive through-substrate interconnect having insulated sidewalls extending into the substrate from the mounting surface toward the light receiving surface to electrically contact the conductive terminal thereon, wherein the through-substrate interconnect is electrically connected to one of the light reactive layers but is electrically isolated from other ones of the light reactive layers and the substrate.
